(19) United States
(12) Patent Application Publication
(10) Pub. No.: US 2010/0282170 A1
(43) Pub. Date: Nov. 11, 2010

(54) VAPOR PHASE GROWTH SUSCEPTOR AND VAPOR PHASE GROWTH APPARATUS

(76) Inventor: Tsuyoshi Nishizawa, Annaka (JP)

Correspondence Address: OLIFF & BERRIDGE, PLC, P.O. BOX 320850, ALEXANDRIA, VA, 22320-4850, US

(21) Appl. No.: 12/744,185

(22) PCT Filed: Nov. 26, 2008
(86) PCT No.: PCT/JP2008/003475

§ 371 Date: May 21, 2010

(30) Foreign Application Priority Data
Dec. 6, 2007 (JP) 2007-316046

(51) Int. Cl. C30B 25/12; C23C 16/458

(52) U.S. Cl. 118/728

(57) ABSTRACT

The present invention provides a vapor phase growth susceptor as a susceptor that supports a wafer in a vapor phase growth apparatus for subjecting a thin film to vapor phase growth on a wafer surface, wherein a pocket configured to accommodate a wafer is formed in the susceptor, many rectangular protrusions are formed of grooves having a mesh pattern on a bottom surface of the pocket, and a groove depth at an outer peripheral portion is shallower than that at a central portion of the bottom surface of the pocket. As a result, problems such as a reduction in film thickness due to a drop in temperature at the wafer outer peripheral portion, warpage at the time of mounting the wafer, deposition on a wafer back surface outer peripheral portion, and others are improved.

### TECHNICAL FIELD

The present invention relates to a vapor phase growth susceptor on which a silicon single crystal substrate is mounted in manufacture of a silicon epitaxial wafer based on vapor phase growth and a vapor phase growth apparatus including the vapor phase growth susceptor.

### BACKGROUND ART

There has been conventionally known a method for manufacturing a silicon epitaxial wafer (which may be referred to as an epitaxial wafer hereinafter) by performing vapor phase growth with respect to a silicon epitaxial layer (which may be referred to as an epitaxial layer hereinafter) on a main surface of a silicon single crystal substrate (which may be referred to as a wafer hereinafter).

Such an epitaxial wafer is manufactured by supplying a silicon raw material gas to a main surface of a wafer arranged in a process vessel while heating the wafer to perform vapor phase growth of an epitaxial layer.

Although a wafer is generally heated while being held by a susceptor having a pocket provided thereto, grooves having a mesh pattern may be formed on a pocket bottom surface of the susceptor (Japanese Patent Application Laid-open No. H8-8198). A main purpose of forming the grooves is to form a passage for a gas, and effects of avoiding displacement when mounting a wafer and enabling easy removal of a wafer from the susceptor can be obtained.

However, a shape of the grooves having the mesh pattern affects a quality of an epitaxial wafer, e.g., warpage when mounting a wafer, a drop in temperature of a wafer outer peripheral portion, or deposition of silicon on an outer peripheral portion of a back surface.

In general, in a single-wafer processing type reactor, to improve a throughput, a wafer is mounted in a high-temperature state that a susceptor has a temperature of 400° C. to 900° C. At this time, since the wafer at the room temperature is precipitously heated on the susceptor, warpage of approximately 1 to 15 mm instantaneously occurs. The warpage at the time of mounting the wafer is far greater than, i.e., 100 times or more the warpage at the time of regular heating, and a scratch may be produced when the susceptor comes into contact with the center of a wafer back surface, or a scratch may be produced when the wafer comes into contact with a transfer machine for mounting wafers.

The susceptor having mesh pattern grooves formed thereto has a tendency that a temperature at the wafer outer peripheral portion is easily dropped as compared with a susceptor having no groove. When a temperature at the wafer outer peripheral portion is dropped, a film thickness of an epitaxial layer is apt to be thinned at the outer periphery, which is a factor that degrades a wafer radial film thickness distribution.

Further, a silicon source gas that has flowed to a space between the wafer back surface and the susceptor may be deposited on the wafer back surface to degrade flatness (see FIG. 4). In a wafer having an oxide film formed on a back surface thereof in particular, although a treatment for removing the oxide film of 0.5 to 1 mm at the outermost peripheral portion on the back surface (a nodule treatment) is carried out, since silicon is deposited on a portion subjected to the oxide film removal treatment in a concentrated manner, the flatness is further degraded in this case.

### DISCLOSURE OF THE INVENTION

In view of the above-described problem, it is an object of the present invention to provide a vapor phase growth susceptor and a vapor phase growth apparatus including this vapor phase growth susceptor that are configured to resolve problems such as a reduction in film thickness caused due to a drop in a temperature at a wafer outer peripheral portion, warpage when mounting a wafer, deposition of silicon on a wafer back surface outer peripheral portion, and the like.

To achieve this object, according to the present invention, there is provided a vapor phase growth susceptor as a susceptor that supports a wafer in a vapor phase growth apparatus for subjecting a thin film to vapor phase growth on a wafer surface, wherein a pocket configured to accommodate a wafer is formed in the susceptor, many rectangular protrusions are formed of grooves having a mesh pattern on a bottom surface of the pocket, and a groove depth at an outer peripheral portion is shallower than that at a central portion of the bottom surface of the pocket.

As described above, in the susceptor in which many rectangular protrusions are formed of the mesh pattern grooves on the bottom surface of the pocket on which the wafer is mounted, when the vapor phase growth susceptor has a configuration that groove depths are not uniform on the bottom surface of the pocket and a groove depth at the outer peripheral portion of the bottom surface of the pocket is shallower than that at the central portion, a reduction in film thickness due to a drop in temperature at the wafer outer peripheral portion can be avoided, and warpage at the time of mounting the wafer and deposition of silicon on the wafer back surface outer peripheral portion can be improved, thereby obtaining a high-quality epitaxial wafer.

Furthermore, it is preferable that the groove depth is changed to be continuously shallowed from the central portion toward the outer peripheral portion.

As described above, in the vapor phase growth susceptor, if a groove depth is changed to be continuously shallowed from the central portion of the bottom surface of the pocket as a wafer mount surface to the outer peripheral portion of the same, the film thickness of the epitaxial layer is not precipitously changed due to a sudden change in temperature at a boundary portion between the central portion and the outer peripheral portion, and the nanotopology or an SFQR (Site flatness least square range) as one of definitions for flatness based on the SEMI standard can be prevented from being degraded, thereby obtaining the high-quality epitaxial wafer.

Moreover, it is preferable that the shallowest groove depth at the outer peripheral portion of the bottom surface of the pocket falls within the range of 0.01 to 0.08 mm and the deepest groove depth at the central portion close to the inner side apart from the outer peripheral portion falls within the range of 0.1 to 0.5 mm.

As described above, in the vapor phase growth susceptor, if the shallowest groove depth at the outer peripheral portion of the bottom surface of the pocket falls within the range of 0.01 to 0.08 mm and the deepest groove depth at the central portion close to the inner side apart from the outer peripheral portion falls within the range of 0.1 to 0.5 mm, a drop in temperature at the outer peripheral portion of the wafer can be avoided, deposition of silicon on the wafer back surface outer peripheral portion can be improved, and slide or warpage of the wafer can be prevented.

Additionally, it is preferable that a boundary between the outer peripheral portion and the central portion has a concentric circles shape and a region of the outer peripheral portion falls within the range of 10 mm to 50 mm from an outer peripheral end of the bottom surface of the pocket.

As described above, in the vapor phase growth susceptor, if the boundary between the outer peripheral portion and the central portion of the bottom surface of the pocket as the wafer mount surface has the concentric circles shape and the region of the outer peripheral portion falls in the range of 10 mm to 50 mm from the outer peripheral end of the bottom surface of the pocket, slide or warpage of the wafer at the time of mounting on the susceptor can be improved, thus obtaining the epitaxial wafer having excellent uniformity.

Further, it is preferable that the susceptor is formed by covering a base material made of graphite with a silicon carbide.

As described above, if the vapor phase growth susceptor has the configuration that the base material formed of the graphite is covered with the silicon carbide, the high-quality susceptor that has a high yield ratio, hardly discharges impurities, and has excellent thermal conductivity and durability can be provided.

Furthermore, the present invention provides a vapor phase growth apparatus that includes at least the vapor phase growth susceptor.

As described above, if the vapor phase growth apparatus including at least the vapor phase growth susceptor is provided, there can be obtained the vapor phase growth apparatus that can avoid a reduction in film thickness due to a drop in temperature at the wafer outer peripheral portion, improve warpage at the time of mounting the wafer and deposition of silicon on the wafer back surface outer peripheral portion, and can acquire a high-quality epitaxial wafer.

According to the present invention, in the vapor phase growth susceptor having many rectangular protrusions formed of mesh pattern grooves on the wafer mount surface, the configuration that the groove depths are not uniform on the wafer mount surface and the outer peripheral portion has a shallower depth than the central portion enables improving a reduction in film thickness due to a drop in temperature at the wafer outer peripheral portion, warpage at the time of mounting a wafer, and deposition of silicon on the wafer back surface outer peripheral portion.

### BRIEF DESCRIPTION OF THE DRAWINGS

FIG. 1 are views showing an example of a vapor phase growth susceptor according to the present invention, where (a) is a cross-sectional view, (b) is a plan view, (c) is an enlarged cross-sectional view of protrusions, and (d) is an enlarged view of top faces of the protrusions;

FIG. 2 is a view showing an example of a vapor phase growth apparatus according to the present invention;

FIG. 3 is a view showing susceptors fabricated in examples and comparative examples; and

FIG. 4 is an explanatory view concerning deposition of silicon on a back surface outer peripheral portion.

### BEST MODE(S) FOR CARRYING OUT THE INVENTION

An embodiment according to the present invention will now be described hereinafter, but the present invention is not restricted thereto.

A conventional susceptor having mesh pattern grooves formed on a pocket bottom surface has a problem such as a reduction in film thickness due to a drop in temperature at a wafer outer peripheral portion, warpage at the time of mounting a wafer, and deposition of silicon on a wafer back surface outer peripheral portion.

To solve the problem, the present inventor examined a shape of grooves having a mesh pattern in each of various susceptors in regard to warpage of a wafer at the time of mounting, an amount of a drop in temperature at a wafer outer periphery, and an amount of deposition of silicon on a wafer back surface portion. As a result, the present inventor revealed that, in a susceptor for manufacture of a silicon epitaxial wafer having many rectangular protrusions formed of grooves having a mesh pattern on a bottom surface of a pocket on which a wafer is mounted, adopting a susceptor having a configuration that groove depths are not uniform on a wafer mount surface as different from a conventional susceptor and an outer peripheral portion has a shallower depth than a central portion enables improving a reduction in film thickness due to a drop in temperature at the wafer outer peripheral portion, warpage at the time of mounting the wafer, and deposition of silicon on the wafer back surface outer peripheral portion. Therefore, radial uniformity of an epitaxial layer can be improved, generation of scratches based on warpage can be suppressed, and flatness can be enhanced based on improving deposition on the back surface, for example.

Although the embodiment according to the present invention will now be described hereinafter with reference to the accompanying drawings, the present invention is not restricted thereto.

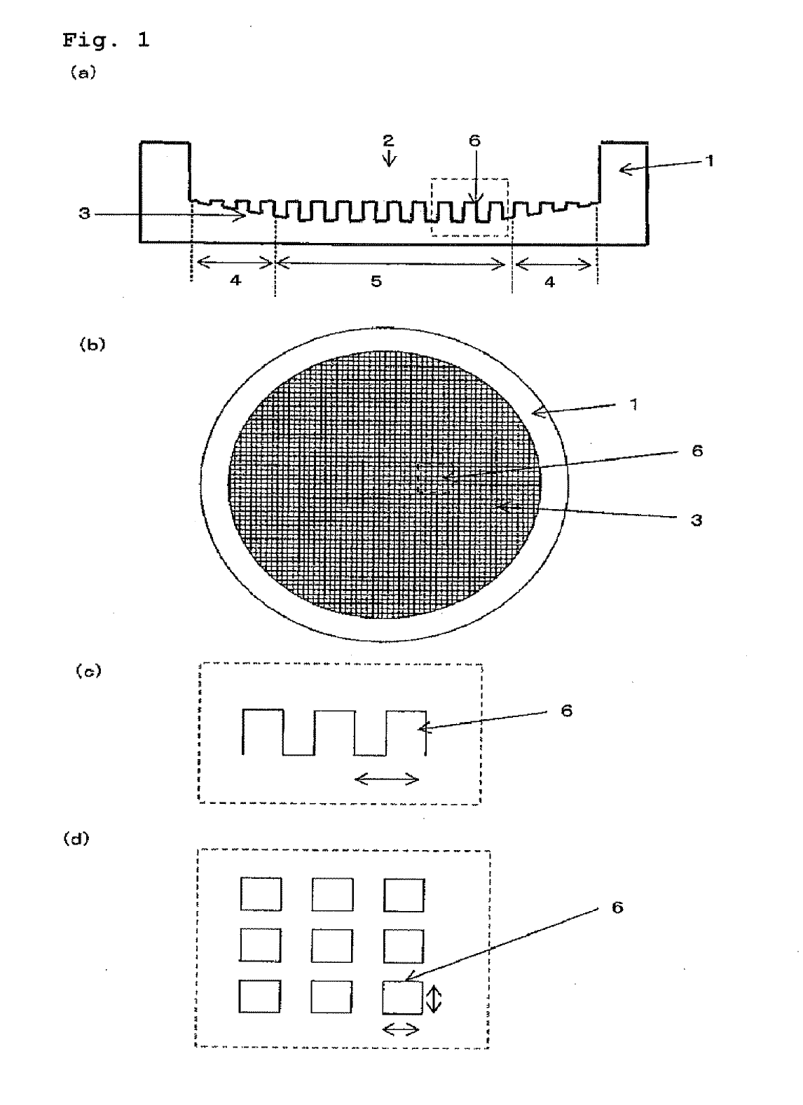

First, FIG. 1 is a view showing an example of a vapor phase growth susceptor according to the present invention.

As shown in FIG. 1(a), a susceptor 1 is formed into, e.g., a substantially discoid shape, and a pocket 2 as a dent portion having a substantially circular shape as seen in a plan view that is configured to accommodate a wafer on a main surface of the susceptor 1 is formed on the main surface. Further, as shown in FIGS. 1(a) and (b), grooves having a mesh pattern are provided as gas passages on a pocket bottom surface 3, thereby forming many rectangular protrusions 6. Furthermore, in the susceptor 1, a groove depth at an outer peripheral portion 4 of the pocket bottom surface is shallower than a groove depth at a central portion (see FIG. 1(a)).

Moreover, FIGS. 1(c) and (d) are enlarged views of the rectangular protrusions 6 formed of the grooves having the mesh patter in the susceptor 1, and it is preferable that the grooves are formed at a pitch of 0.6 to 2 mm (see FIG. 1(c)) and each protrusion formed by being surrounded by the grooves has a top face which is a square having each side of 0.1 to 0.5 mm (see FIG. 1(d)). Additionally, the grooves having the mesh pattern avoid displacement when mounting a wafer, and they can also demonstrate an effect of facilitating removal of a wafer from the susceptor 1 when taking out the wafer.

Further, in the susceptor 1, it is preferable for a change in groove depth that occurs from the central portion 5 to the outer peripheral portion 4 to be continuously shallowed. If the change in groove depth that occurs from the central portion to the outer peripheral portion is continuous, a temperature is not precipitously changed at a boundary portion, and the nanotopology or the SFQR can be prevented from being degraded due to a drastic change in film thickness of an epitaxial layer. To avoid such degradation in quality, a continuous change in groove depth is preferable.

A drop in temperature at the wafer outer peripheral portion concerns the groove depth, and there is a tendency that a drop in temperature becomes large as a groove depth increases. Furthermore, since deposition of silicon on a back surface also has a tendency that deposition is apt to occur as a groove depth increases, a shallower groove depth at the outer peripheral portion is desirable, but the gas passages are not closed and the wafer does not readily slide at the time of mounting on the susceptor if the shallow grooves are formed without completely eliminating the grooves. Therefore, it is preferable that the shallowest groove depth at the outer peripheral portion 4 of the pocket bottom surface falls within the range of 0.01 to 0.08 mm and the deepest groove depth at the central portion 5 close to the inner side apart from the outer peripheral portion 4 falls within the range of 0.1 to 0.5 mm. Such a susceptor can avoid a drop in temperature at the wafer outer periphery, improve deposition of silicon on the back surface, and prevent slide and warpage of the wafer.

Moreover, in the susceptor 1, it is preferable that a boundary between the outer peripheral portion 4 and the central portion 5 of the pocket bottom surface has a concentric circles shape and a region of the outer peripheral portion 4 falls within the range of 10 mm to 50 mm from an outer peripheral end of the pocket bottom surface.

Slide and warpage of the wafer at the time of mounting on susceptor can be improved as the wafer mount surface has deeper grooves. Therefore, on the pocket bottom surface, a larger area of the central portion having the deeper grooves is desirable. However, when the area of the central portion is extremely increased, an area of the outer peripheral portion having shallower grooves is shallowed, and a problem such as a drop in temperature at the outer peripheral portion and an increase in deposition amount of silicon on the back surface outer peripheral portion occurs as described above. Therefore, it is preferable for the region of the outer peripheral portion to fall within the range of 10 mm to 50 mm from the outer peripheral end of the pocket bottom surface. Additionally, when the boundary between the outer peripheral portion and the central portion has the concentric circles shape, an epitaxial wafer having excellent radial uniformity can be manufactured.

Further, as materials forming the susceptor 1, using graphite for a base material and a silicon carbide for a film is preferable. Preferably using the graphite as the base material concerns the fact that a mainstream of a heating scheme of a vapor phase growth apparatus during initial phases of development is high-frequency induction heating, and it also has merits that a high-purity product can be readily obtained, processing is easy, thermal conductivity is excellent, damages are hardly produced, and others. However, the graphite has problems that it may possibly discharge an occluded gas during a process since it is a porous body, that a surface of the susceptor changes into a silicon carbide due to a reaction of the graphite and a raw material gas during a vapor phase growth process, and others. Therefore, a configuration that the surface is covered with a silicon carbide film from the beginning is general. This silicon carbide film is usually formed with a thickness of 50 to 200 μm based on CVD (a chemical vapor deposition method).

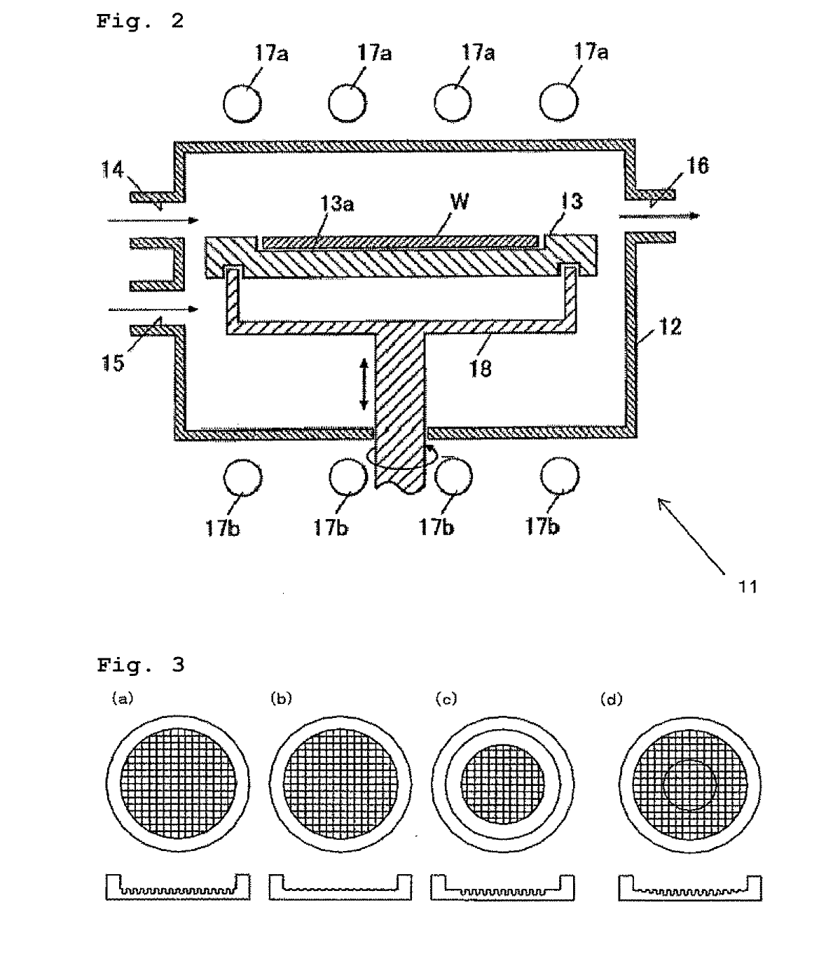

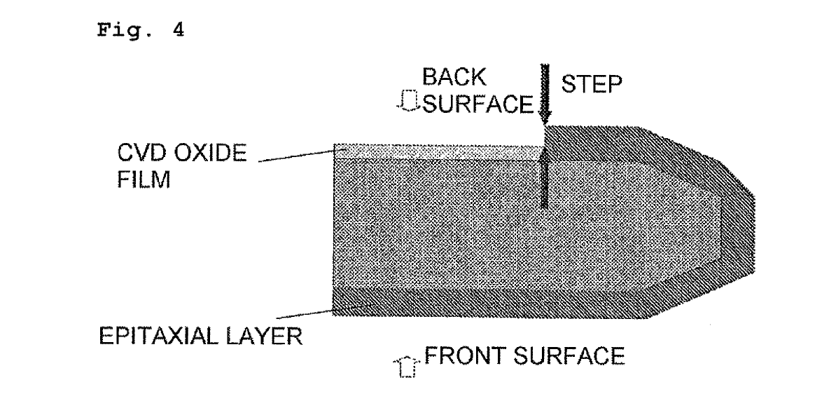

Then, FIG. 2 shows an example of a vapor phase growth apparatus according to the present invention. As shown in FIG. 2, a vapor phase growth apparatus 11 includes a process vessel 12 formed of transparent quartz and a susceptor 13 that is provided in the process vessel and supports a silicon substrate (a wafer) W on an upper surface thereof. The susceptor 13 provided in this vapor phase growth apparatus 11 is a susceptor according to the present invention, and the susceptor 1 depicted in FIG. 1 can be utilized, for example.

To the process vessel 12 is provided a vapor phase growth gas introduction tube 14 through which a vapor phase growth gas containing a raw material gas (e.g., trichlorosilane) and a carrier gas (e.g., hydrogen) is introduced into an upper region of the susceptor to be supplied to a main surface of a wafer on the susceptor. Additionally, a purge gas tube 15 through which a purge gas (e.g., hydrogen) is introduced to a lower region of the susceptor is provided on the same side of the process vessel where the vapor phase growth gas introduction tube is provided.

Further, an exhaust tube 16 through which gases (the vapor phase growth and purge gases) in the process vessel are discharged is provided on the side opposite to the side where the vapor phase growth gas introduction tube and the purge gas introduction tube are provided.

A plurality of heaters 17a and 17b that heat the process vessel 12 from the upper and lower sides are provided outside the process vessel. As the heater, there is, e.g., a halogen lamp. It is to be noted that the number of heaters is determined for convenience' sake, but the present invention is not restricted thereto.

Furthermore, a susceptor support member 18 that supports the susceptor 13 is provided on the back surface of the susceptor 13. This susceptor support member can move in the vertical direction and can rotate.

Moreover, the above-described vapor phase growth apparatus 11 including the vapor phase growth susceptor according to the present invention can be utilized to manufacture an epitaxial wafer based on the following method. First, a wafer W is put into the process vessel 12 adjusted to an input temperature (e.g., 650° C.), and it is mounted on a pocket 13a on the susceptor upper surface in such a manner that the main surface of the wafer W faces the upper side. Here, a hydrogen gas is introduced into the process vessel 12 through the vapor phase growth gas introduction tube 14 and the purge gas tube 15 on a stage before putting the wafer W. Then, the wafer on the susceptor 13 is heated to a hydrogen heat treatment temperature (e.g., 1110 to 1180° C.) by the heaters 17a and 17b.

Subsequently, vapor phase etching for removing a native oxide formed on the main surface of the wafer W is carried out. It is to be noted that this vapor phase etching is performed immediately before vapor phase growth as the next process.

Then, a temperature of the wafer W is dropped to a desired growth temperature (e.g., 1060 to 1150° C.), and a raw material gas (e.g., trichlorosilane) is supplied to the main surface of the wafer W through the vapor phase growth gas introduction tube 14 and a purge gas (a carrier gas: e.g., hydrogen) is supplied to the same through the purge gas introduction tube 15 in substantially parallel, respectively, whereby an epitaxial layer is subjected vapor phase growth on the main surface of the wafer W to manufacture an epitaxial wafer. It is to be noted that the purge gas is supplied with a pressure higher than that of the raw material gas. This supply is performed in the above-described manner in order to prevent the raw material gas from advancing to a lower space from a gap between the process vessel 12 and the susceptor 13.

At last, a temperature of the epitaxial wafer is dropped to an ejection temperature (e.g., 650° C.) and the epitaxial wafer is carried to the outside of the process vessel 12.

When the epitaxial wafer is manufactured by using the vapor phase growth apparatus including the vapor phase growth susceptor according to the present invention, in the vapor phase growth susceptor having many rectangular protrusions formed of the grooves having the mesh pattern on the wafer mount surface, the configuration that the groove depths are not uniform on the wafer mount surface and the outer peripheral portion is shallower than the central portion enables improving a problem, e.g., degradation in film thickness uniformity of the epitaxial layer based on a reduction in film thickness due to a drop in temperature at the wafer outer peripheral portion, generation of scratches due to warpage at the time of mounting the wafer, degradation in flatness due to deposition of silicon on the wafer back surface outer peripheral portion, and others.

Although the present invention will now be more specifically described hereinafter based on an example and comparative examples, the present invention is not restricted thereto.

### Example, Comparative Examples

Susceptors each having a shape shown in FIG. 3 were fabricated as Example 1 and Comparative Examples 1, 2, and 3, and these susceptors were utilized to manufacture epitaxial wafers. FIG. 3(a) shows a vapor phase growth susceptor having a conventional shape, and a pocket bottom surface has a groove depth of 0.1 mm, which is uniform on the entire surface (Comparative Example 1). Further, a susceptor depicted in FIG. 3(b) has a groove depth of 0.02 mm on the entire surface (Comparative Example 2). Furthermore, as shown in FIG. 3(c), a susceptor having a shape that a groove depth is 0.1 mm in a region of a central portion within a diameter 180 mm of a pocket bottom surface and an outer side beyond the diameter 180 mm has no groove (Comparative Example 3) was fabricated. Moreover, as shown in FIG. 3(d), a susceptor having a shape that a groove depth on a pocket bottom surface is 0.1 mm in a region of a central portion within a diameter 180 mm and it is changed to 0.02 mm from this region toward an outer peripheral side in an inclined manner (Example 1) was fabricated.

It is to be noted that the respective susceptors according to Example 1 and Comparative Examples 1 to 3 were standardized with a silicon carbide film thickness of 100 μm, a pocket diameter of 208 mm, a mesh pitch of 0.7 mm, and a groove width of 0.4 mm.

### (1) Approximate Calculation of Drop in Temperature at Outer Periphery

First, as a test wafer for temperature evaluation, a wafer obtained by ion-implanting phosphor as an n-type impurity into a p-type silicon wafer having a diameter of 200 cm, a resistivity of 10 Ω·cm, and a plane orientation (100) of a main surface was additionally prepared. This ion implantation was carried out with ion acceleration energy of 500 KeV and a dose amount of 3.0×10¹⁴/cm². The ion-implanted test wafer was subjected to a heat treatment for 30 minutes in a thermal diffusion furnace having known temperature characteristics, then a sheet resistance was measured, and a calibration line was fabricated in advance so that the sheet resistance can be converted into a treatment temperature.

Then, each susceptor according to Example 1 and Comparative Examples 1 to 3 was utilized to perform a heat treatment for 30 minutes at a predetermined temperature with respect to an evaluation wafer subjected to the same treatment as the ion-implanted test wafer for temperature evaluation, then a sheet resistance was measured by using a four-probe measuring instrument, and the previously obtained calibration line was utilized to convert the sheet resistance into a temperature. The sheet resistance measurement position was each of a position, which is 5 mm from an outer peripheral end of the wafer, and a position, which is 10 mm from the same, and a difference between resistances was calculated as an amount of drop in temperature.

Furthermore, each susceptor according to Example 1 and Comparative Examples 1 to 3 and a vapor phase growth apparatus including this susceptor were used for fabricating an epitaxial wafer obtained by performing a nodule treatment with respect to a P-type wafer having a diameter of 200 mm, a crystal orientation of <100>, and a back surface CVD oxide film thickness of 500 μm and then growing a non-doped epitaxial layer to have a thickness of 70 μm.

Quality of each epitaxial wafer fabricated by using each susceptor according to Example 1 and Comparative Examples 1 to 3 was evaluated based on a four-pattern evaluation method including (2) measurement of a deposition amount of silicon on a back surface outer peripheral portion, (3) a scratch defect due to warpage when mounting the wafer, and (4) slide when mounting the wafer.

### (2) Measurement of Deposition Amount of Silicon on Back Surface Outer Peripheral Portion

Since silicon is not deposited on a back surface CVD oxide film but silicon is deposited from a portion subjected to the nodule treatment, a height profile of the portion subjected to the nodule treatment from the CVD oxide film was measured.

(3) Scratch Defect Due to Warpage when Mounting Wafer

After epitaxial growth, each wafer was subjected to visual appearance inspection under a halogen lamp to check presence/absence of scratches.

(4) Slide when Mounting Wafer

Whether each wafer slides in a pocket when mounting the wafer on the susceptor in an ordinary-temperature state was evaluated based on visual inspection.

Table 1 shows a result of the approximate calculation of a drop in temperature at the outer periphery performed by using each susceptor according to Example 1 and Comparative Examples 1 to 3 and a result of the quality evaluation in each epitaxial wafer fabricated by using each susceptor according to Example 1 and Comparative Examples 1 to 3.

TABLE 1

| | | DROP IN | DEPOSITION AMOUNT | SCRATCH DEFECT | SLIDE | |
|---|---|---|---|---|---|---|
| | | TEMPERATURE | OF SILICON ON | DUE TO WARPAGE | WHEN | |
| | | AT WAFER | BACK SURFACE OUTER | WHEN MOUNTING | MOUNTING | OTHER |
| | GROOVE DEPTH | OUTER PERIPHERY | PERIPHERAL PORTION | WAFER | WAFER | QUALITY |
| COMPARATIVE | UNIFORMLY ON | −1.6° C. | 7.0 μm | NONE | NONE | — |
| EXAMPLE 1 | ENTIRE SURFACE | | | | | |
| | 0.1 mm | | | | | |
| COMPARATIVE | UNIFORMLY ON | −0.5° C. | 3.5 μm | PRESENT | PRESENT | — |
| EXAMPLE 2 | ENTIRE SURFACE | | | | | |
| | 0.02 mm | | | | | |
| COMPARATIVE | CENTRAL | −0.2° C. | 3.4 μm | NONE | PRESENT | FILM |
| EXAMPLE 3 | PORTION: 0.1 mm | | | | | THICKNESS |
| | OUTER | | | | | DIFFERENCE |
| | PERIPHERAL | | | | | AT |
| | PORTION: NO | | | | | BOUNDARY |
| | GROOVE | | | | | PORTION |
| EXAMPLE 1 | CENTRAL | −0.4° C. | 3.5 μm | NONE | NONE | — |
| | PORTION: 0.1 mm | | | | | |
| | OUTER | | | | | |
| | PERIPHERAL | | | | | |
| | PORTION: | | | | | |
| | 0.02~0.2 mm | | | | | |
| | (INCLINED) | | | | | |

As can be understood from Table 1, a result that a drop in temperature at the wafer outer periphery of each epitaxial wafer fabricated by using each susceptor according to Example 1 and Comparative Examples 2 and 3 and a deposition amount of silicon on the back surface outer peripheral portion are smaller than those in Comparative Example 1 was obtained. On the other hand, in the susceptor according to Comparative Example 1 in which grooves of 0.1 mm are uniformly formed on the entire pocket bottom surface, a temperature at the wafer outer periphery was considerably dropped, and a deposition amount of silicon on the back surface outer peripheral portion was large. In particular, since a drop in temperature at the outer periphery was minimum and a silicon deposition amount was small when the susceptor according to Comparative Example 3 having no groove at the outer peripheral portion was used, it was revealed that the drop in temperature at the wafer outer periphery became small as a depth of the grooves having the mesh pattern at the outer peripheral portion of the pocket bottom surface was shallowed and the silicon deposition amount on the back surface outer peripheral portion became decrease as a depth of the grooves at the outer peripheral portion was shallowed. Further, it was found out that the groove depth at the central portion of the pocket bottom surface did not concern the drop in temperature at the wafer outer periphery and deposition of silicon on the back surface outer peripheral portion.

On the other hand, it was understood that, since the scratch defect due to warpage at the time of mounting the wafer occurred in Comparative Example 2 alone in which the grooves having the mesh pattern at the central portion were shallow, this defect hardly occurs when the groove depth at the central portion was deep, and the groove depth at the outer peripheral portion did not affect. However, it was found out that slide of the wafer occurred when the grooves at the outer peripheral portion were completely eliminated like Comparative Example 3. Based on this fact, it was revealed that slide did not occur when the grooves are formed even though they are shallow like Example 1.

Moreover, it was found out that, when the groove depth was precipitously changed like Comparative Example 3, a shape of film thickness of the epitaxial layer varied at a corresponding portion, and flatness quality, e.g., the nanotopology might be affected. Therefore, it was revealed that, when changing the groove depth, gradually changing the groove depth like Example 1 rather than precipitously changing the same was preferable.

Based on the above-described result, using the vapor phase growth susceptor in which the groove depth at the outer peripheral portion of the pocket bottom surface as the wafer mount portion is formed shallower than that at the central portion of the same like Example 1 enables improving, e.g., a reduction in film thickness due to a drop in temperature at the wafer outer peripheral portion, warpage when mounting the wafer, and deposition of silicon on the wafer back surface outer peripheral portion. Additionally, it was found that changing the groove depth to be continuously shallowed from the central portion to the outer peripheral portion of the pocket bottom surface like Example 1 enables manufacturing a high-quality epitaxial wafer without affecting the flatness quality, e.g., the nanotopology.

It is to be noted that the present invention is not restricted to the foregoing embodiment. The foregoing embodiment is just an exemplification and any examples, which have substantially the same configuration and demonstrate the same effects as the technical concept described in claims of the present invention are included in the technical scope of the present invention.

1-6. (canceled)

7. A vapor phase growth susceptor as a susceptor that supports a wafer in a vapor phase growth apparatus for subjecting a thin film to vapor phase growth on a wafer surface, wherein a pocket configured to accommodate a wafer is formed in the susceptor, many rectangular protrusions are formed of grooves having a mesh pattern on a bottom surface of the pocket, and a groove depth at an outer peripheral portion is shallower than that at a central portion of the bottom surface of the pocket.

8. The vapor phase growth susceptor according to claim 7, wherein the groove depth is changed to be continuously shallowed from the central portion toward the outer peripheral portion.

9. The vapor phase growth susceptor according to claim 7, wherein the shallowest groove depth at the outer peripheral portion of the bottom surface of the pocket falls within the range of 0.01 to 0.08 mm, and the deepest groove depth at the central portion close to the inner side apart from the outer peripheral portion falls within the range of 0.1 to 0.5 mm.

10. The vapor phase growth susceptor according to claim 8, wherein the shallowest groove depth at the outer peripheral portion of the bottom surface of the pocket falls within the range of 0.01 to 0.08 mm, and the deepest groove depth at the central portion close to the inner side apart from the outer peripheral portion falls within the range of 0.1 to 0.5 mm.

11. The vapor phase growth susceptor according to claim 7, wherein a boundary between the outer peripheral portion and the central portion has a concentric circles shape, and a region of the outer peripheral portion falls within the range of 10 mm to 50 mm from an outer peripheral end of the bottom surface of the pocket.

12. The vapor phase growth susceptor according to claim 8, wherein a boundary between the outer peripheral portion and the central portion has a concentric circles shape, and a region of the outer peripheral portion falls within the range of 10 mm to 50 mm from an outer peripheral end of the bottom surface of the pocket.

13. The vapor phase growth susceptor according to claim 9, wherein a boundary between the outer peripheral portion and the central portion has a concentric circles shape, and a region of the outer peripheral portion falls within the range of 10 mm to 50 mm from an outer peripheral end of the bottom surface of the pocket.

14. The vapor phase growth susceptor according to claim 10, wherein a boundary between the outer peripheral portion and the central portion has a concentric circles shape, and a region of the outer peripheral portion falls within the range of 10 mm to 50 mm from an outer peripheral end of the bottom surface of the pocket.

15. The vapor phase growth susceptor according to claim 7, wherein the susceptor is formed by covering a base material made of graphite with a silicon carbide.

16. The vapor phase growth susceptor according to claim 8, wherein the susceptor is formed by covering a base material made of graphite with a silicon carbide.

17. The vapor phase growth susceptor according to claim 9, wherein the susceptor is formed by covering a base material made of graphite with a silicon carbide.

18. The vapor phase growth susceptor according to claim 10, wherein the susceptor is formed by covering a base material made of graphite with a silicon carbide.

19. The vapor phase growth susceptor according to claim 11, wherein the susceptor is formed by covering a base material made of graphite with a silicon carbide.

20. The vapor phase growth susceptor according to claim 14, wherein the susceptor is formed by covering a base material made of graphite with a silicon carbide.

21. A vapor phase growth apparatus including the vapor phase growth susceptor according to claim 7.

22. A vapor phase growth apparatus including the vapor phase growth susceptor according to claim 8.

23. A vapor phase growth apparatus including the vapor phase growth susceptor according to claim 9.

24. A vapor phase growth apparatus including the vapor phase growth susceptor according to claim 10.

25. A vapor phase growth apparatus including the vapor phase growth susceptor according to claim 11.

26. A vapor phase growth apparatus including the vapor phase growth susceptor according to claim 14.

27. A vapor phase growth apparatus including the vapor phase growth susceptor according to claim 15.

28. A vapor phase growth apparatus including the vapor phase growth susceptor according to claim 20.
